(19) United States
(12) Patent Application Publication
(10) Pub. No.: US 2026/0287348 A1
(43) Pub. Date: Sep. 24, 2026

(54) Laser Unit for a Rotary Laser

(71) Applicant: Robert Bosch GmbH, Stuttgart (DE)

(72) Inventor: Tobias Roehm, Wildberg-Sulz (DE)

(21) Appl. No.: 19/570,619

(22) Filed: Mar. 18, 2026

(30) Foreign Application Priority Data
Mar. 20, 2025 (DE) 10 2025 110 732.7

(51) Int. Cl. G01C 15/00; H01S 5/00; H01S 5/02208; H01S 5/023

(52) U.S. Cl. CPC G01C 15/002; H01S 5/0071; H01S 5/02208; H01S 5/023

(57) ABSTRACT

A laser unit for a rotary laser, which has a drive unit for the purpose of rotating a spindle for the rotary drive of a laser beam, is disclosed. A beam deflector for deflecting the laser beam is arranged on the spindle. The drive unit has a stator with a carrier tube and a rotor for the rotary drive of the spindle. The laser unit has a laser diode holder that can be arranged at least in sections within the carrier tube. The laser diode holder has a tubular base body with an interior receptacle in which a laser diode is arranged. The tubular base body of the laser diode holder has a circumferential collar which, in the circumferential direction of the laser diode holder, has at least two radial extensions for a detachable connection to a press-fitting device for press-fitting the laser diode holder into the carrier tube.

This application claims priority under 35 U.S.C. § 119 to patent application no. DE 10 2025 110 732.7, filed on Mar. 20, 2025 in Germany, the disclosure of which is incorporated herein by reference in its entirety.

### BACKGROUND

The present disclosure relates to a laser unit for a rotary laser, which, for the purpose of rotating a laser beam, has a drive unit for the rotary drive of a spindle, wherein a beam deflector for deflecting the laser beam is arranged on the spindle, wherein the drive unit has a stator with a carrier tube and a rotor for the rotary drive of the spindle, wherein the laser unit has a laser diode holder that can be arranged at least in sections within the carrier tube, and wherein the laser diode holder has a tubular base body with an interior receptacle in which a laser diode is arranged.

A laser unit for a rotary laser is known from the prior art, wherein the rotary laser, for the purpose of rotating a laser beam, has a drive unit for the rotary drive of a spindle, wherein a beam deflector for deflecting the laser beam is arranged on the spindle, and wherein the drive unit has a stator with a carrier tube and a rotor for the rotary drive of the spindle. The laser unit has a laser diode holder that can be arranged in sections in the carrier tube. The laser diode holder has a tubular base body with an interior receptacle in which a laser diode is arranged.

### SUMMARY

The disclosure relates to a laser unit for a rotary laser, which has a drive unit, for the purpose of rotating a laser beam, for the rotary drive of a spindle, wherein a beam deflector for deflecting the laser beam is arranged on the spindle, and wherein the drive unit has a stator with a carrier tube and a rotor for the rotary drive of the spindle. The laser unit has a laser diode holder that can be positioned at least partially within the carrier tube, wherein the laser diode holder comprises a tubular base body with an interior receptacle in which a laser diode is disposed. The tubular base body of the laser diode holder has a circumferential collar that has at least two radial extensions in the circumferential direction of the laser diode holder for detachable connection to a press-fitting device used for press-fitting the laser diode holder into the carrier tube.

The disclosure thus enables the provision of a laser unit in which the at least two radial extensions allow for exact and precise positioning within the laser diode holder.

Preferably, the detachable connection is designed to transmit compressive and/or tensile forces.

This enables safe and reliable handling of the laser diode holder in a simple manner.

Preferably, the circumferential collar extends away from the tubular base body in the shape of a plate.

This makes it easy and uncomplicated to provide a suitable circumferential collar.

Preferably, the at least two radial extensions are designed to form a detachable bayonet connection with the press-fitting device.

This enables a secure and reliable connection between the two radial extensions and the press-fitting device.

Furthermore, the present disclosure relates to a press-fitting device for press-fitting a laser diode holder of a laser unit into a carrier tube of a stator of a drive unit of a rotary laser, with a first holding part for holding the carrier tube and a second holding part for holding the laser diode holder, wherein the second holding part has at least one undercut in sections in the circumferential direction for forming a detachable connection with the laser unit.

The disclosure thus makes it possible to provide a press-fitting device in which the second holding part with the undercut enables the laser diode holder to be arranged exactly and precisely in the carrier tube.

Preferably, the laser diode holder and the second holding part form a bayonet connection in a locked position for press-fitting the laser diode holder into the carrier tube.

This ensures a secure and reliable connection for the press-fitting process.

The bayonet connection is preferably designed to transmit compressive and/or tensile forces.

This makes it easy to achieve an exact and precise arrangement of the laser diode holder in the carrier tube.

Furthermore, the present disclosure relates to a rotary laser with a laser unit as described above.

The disclosure thus makes it possible to provide a rotary laser with a laser unit in which an exact and precise arrangement in the laser diode holder can be made possible by the at least two radial extensions.

Furthermore, the present disclosure relates to a method for mounting a laser diode holder of a laser unit of a rotary laser in a carrier tube of a stator, which comprises the following steps:
positioning the laser diode holder in a joining position on a first holding part of a press-fitting device,
rotating the laser diode holder by a predetermined angle of rotation along a circumferential direction to position it in a locked position in which the laser diode holder and the first holding part form a bayonet connection,
fixing the stator to a second holding part of the press-fitting device,
pressing the laser diode holder into the interior receptacle of the stator along its longitudinal extension by applying force to the first holding part relative to the second holding part,
rotating the laser diode holder relative to the press-fitting device counter to the circumferential direction to rotate the laser diode holder from the locked position to the joining position, and
removing the first and second holding parts from the laser diode holder and the carrier tube of the stator.
   The disclosure thus makes it possible to provide a method for mounting a laser diode holder of a laser unit of a rotary laser, in which an exact and precise arrangement of the laser diode holder in the carrier tube of the rotary laser can be made possible.

Preferably, the laser diode holder has at least two radial extensions and the second holding part has at least one undercut, wherein the at least two radial extensions are arranged in the at least one undercut to form the bayonet connection.

This enables a secure and reliable connection between the laser diode holder and the press-fitting device.

### BRIEF DESCRIPTION OF THE DRAWINGS

The disclosure is explained in more detail in the following description with reference to the exemplary embodiments shown in the drawings. They show:

FIG. 1 a perspective view of a rotary laser with a laser unit according to the disclosure,

FIG. 2 a cross-sectional view of a stator associated with the rotary laser of FIG. 1 with a laser diode holder and the laser unit,

FIG. 3 a perspective view of a base plate associated with the rotary laser of FIG. 1 with the stator of FIG. 2 and two inclination sensors associated with the rotary laser,

FIG. 4 a perspective cross-sectional view of a press-fitting device with the laser diode holder and the stator of FIG. 2 and FIG. 3,

FIG. 5 a cross-sectional view of a press-fitting device with the laser diode holder and the stator of FIG. 4,

FIG. 6 a perspective view of a holding part associated with the press-fitting device of FIG. 4 and FIG. 5 and the laser diode holder of FIG. 2 to FIG. 5 in a first position,

FIG. 7 a perspective view of the holding part and the laser diode holder of FIG. 6 in a further position,

FIG. 8 a perspective view of the holding part from FIG. 4 to FIG. 7,

FIG. 9 a perspective view of the laser diode holder from FIG. 2 to FIG. 6 as seen from a bottom side,

FIG. 10 a cross-sectional view of the stator with the laser diode holder from FIG. 2 to FIG. 6, and

FIG. 11 a schematic view of a measuring process for an adjustment turning.

### DETAILED DESCRIPTION

Elements having the same or a comparable function are provided with the same reference signs in the figures and are described in detail only once.

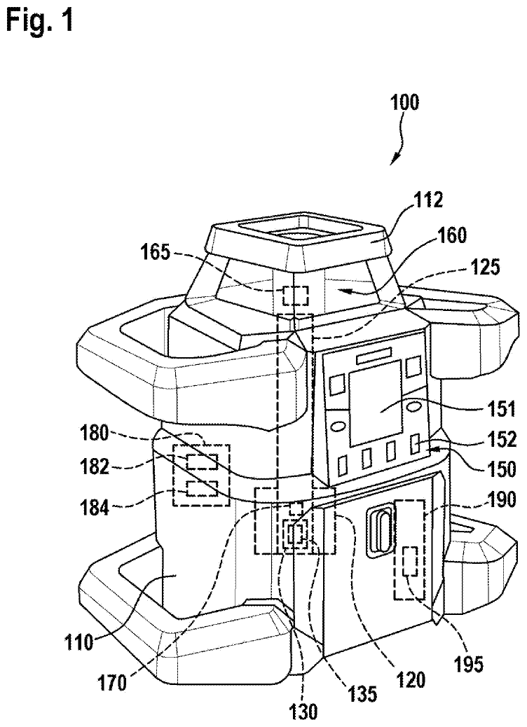

FIG. 1 illustrates an exemplary rotary laser 100 with a housing 110, in which a laser unit 130 with a laser diode 135 for generating a laser beam is arranged. A “rotary laser” may also be understood in the context of the present disclosure to mean a construction laser or a leveling laser. Furthermore, an example of a drive unit 120 for rotating a spindle 125 is arranged in the housing 110.

The laser unit 130 is illustratively arranged on the spindle 125 such that rotation of the spindle 125 rotates the laser beam generated by the laser unit 130 in an associated plane. To this end, the spindle 125 is preferably associated with a rotary head 160 with a beam deflector 165. The beam deflector 165 is preferably configured to deflect the laser beam, as a result of which the laser beam projects the associated plane. Depending on the design of the rotary laser 100, the projected plane may be horizontal, vertical, or, e.g., at a defined inclination angle with respect to the earth's surface. The drive unit 120 is preferably configured as an electric motor.

Moreover, an electronic unit 190 with a control and monitoring device 195 is preferably arranged in the housing 110. The control and monitoring device 195 is preferably configured to control the laser output of the laser unit 130 depending on a mode of operation. A rotational speed of the spindle 125 of the drive unit 120 is thus controlled or regulated. Preferably, a determination unit 170 is associated with the spindle 125 for this purpose.

According to one embodiment, the housing 110 is associated with a protective cage 112 associated with the rotary head 160 to protect against the rotary head 160 striking something.

The electronic unit 190 is preferably associated with a operating unit 150 with a display 151 and an input unit 152. The operating unit 150 is preferably connected to the electronic unit 190, in particular to the control and monitoring device 195, for control or regulation. The input unit 152 comprises at least one keypad. Alternatively, it is also conceivable that the input unit 152 comprises a control dial, a touch screen, a slider, a remote control, or the like. For example, via the input unit 152, a user may enter a rotational speed for the spindle 125. Alternatively, the rotational speed of the laser unit 130 is automatically controllable in one mode of operation.

Preferably, the rotary laser 100 comprises a leveling unit 180. The leveling unit 180 preferably comprises at least one inclination sensor 184 configured to determine an inclination of the rotary head 160, in particular of the beam deflector 165, and/or of the laser unit 130, relative to a predetermined, preferably horizontal direction or to a vertical direction. Moreover, the leveling unit 180 preferably comprises at least one inclination adjustment motor 182 configured to align the rotary head 160, in particular the beam deflector 165, and/or the laser unit 130, depending on a position determined by the at least one inclination sensor 184, preferably an inclination of the laser unit 130 and/or the rotary head 160, preferably in the vertical direction.

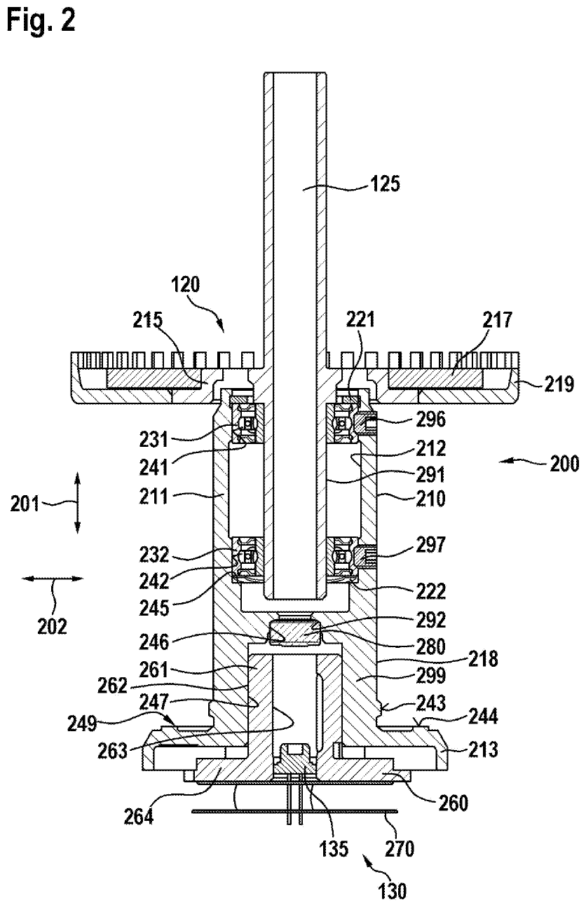

FIG. 2 shows the spindle 125 of FIG. 1, which is illustratively mounted by way of a bearing arrangement 200 in a stator 210 associated with the drive unit 120 of FIG. 1. As an example, the stator 210 has a cylindrical carrier tube 211 with an interior receptacle 212. The interior receptacle 212 illustratively accommodates the bearing arrangement 200, which comprises two bearing elements 231, 232 for supporting the spindle 125.

Preferably, the stator 210 has at least one recess arranged perpendicular to the interior receptacle 212. The at least one recess is illustratively arranged along a longitudinal extension 201 of the spindle 125 in the region of at least one bearing surface 241, 242. Preferably, a clamping connection is formed between a clamping element 296, 297 associated with one of the at least one recess and an outer circumference of one of the two bearing elements 231, 232. By way of example, the clamping elements 296, 297 are designed as screws, in particular grub screws. The clamping elements 296, 297 allow play between the stator 210 and the two bearing elements 231, 232 to be eliminated at least substantially, i.e., within the range of customary manufacturing tolerances.

For illustrative purposes, an upper bearing surface 241 is associated with bearing element 231, and a lower bearing surface 242 is associated with bearing element 232. Preferably, the bearing surface 242, which is thus assigned to the illustratively lower end of the spindle 125, has an abutment surface 245 in the interior receptacle 212 for abutment of the bearing element 232 assigned to the bearing surface 242 along the longitudinal extension 201 of the spindle 125.

Furthermore, FIG. 2 illustrates the laser unit 130 of FIG. 1. The laser unit 130 comprises, for example, a laser module housing 299 having an interior receptacle 247 for outputting or emitting a collimated laser beam generated by the laser diode 135. The laser module housing 299 may be formed in one piece with the stator 210.

For collimation of the laser beam, the laser unit 130 preferably has a collimation lens 280. In this configuration, the collimating lens 280 is preferably arranged and secured in an illustrative upper receptacle section 246 of the interior receptacle 292 of the laser module housing 299. The collimating lens 280 is preferably secured in the interior receptacle 292 or the receptacle section 246 by way of a material bond and/or a press fit.

Furthermore, illustratively, a laser diode holder 260 is disposed in the interior receptacle 292, particularly in an illustratively lower receptacle section 246. Preferably, a press fit is formed, at least in some sections, between the outer circumference 262 of the laser diode holder 260 and the receptacle section 246.

The laser diode holder 260 illustratively has an interior receptacle 263. In the interior receptacle 263, the laser diode 135 for generating a laser beam is preferably arranged. The laser diode 135 is preferably arranged on a printed circuit board 270. Preferably, the printed circuit board 270 is configured to be a flexible printed circuit board. For illustrative purposes, the printed circuit board 270 is located on the bottom side of the laser diode holder 260, facing away from the stator 210. Preferably, the printed circuit board 270 is fixed to the laser diode holder 260 by way of a material bond. According to one embodiment, the material bond is an adhesive bond. Here, the adhesive is preferably double-sided adhesive tape.

Preferably, the determination unit 170 of FIG. 1 is associated with the spindle 125. The determination unit 170 has, for example, a toothed disc 219 and a photointerrupter (not shown). The toothed disc 219 illustratively has a receptacle for at least partially receiving a magnetic disc 217. The magnetic disc 217 forms an example of a rotor of the drive unit 120.

Preferably, the spindle 125 has a cover element 215. The cover element 215 preferably serves as a bearing seat or magnetic seat. The spindle 125 is preferably connected to the cover element 215. Here, the cover element 215 is illustratively arranged on an outer circumference 291 of the spindle 125 and extends the spindle 125 in the radial direction 202 of the spindle 125. Preferably, the cover element 215 is disc-shaped. As an example, the cover element 215 is formed integrally with the spindle 125. The toothed disc 219 and the cover element 215 illustratively form the receptacle for at least partially receiving the magnetic disc 217. The toothed disc 219 is preferably connected to the magnetic disc 217. Preferably, the toothed disc 219 is connected to the magnetic disc 217 by way of an adhesive bond. Alternatively, the cover element 215 is attached to the spindle 125.

Preferably, the spindle 125 is assigned a locking element 221 for locking on the stator 210 or in the carrier tube 211. Preferably, at least one spring element 222 is arranged along the longitudinal extension 201 of the spindle 125 between the locking element 221 and a respective associated bearing element 231, 232 of the two bearing elements 231, 232. The locking element 221 can be designed as a snap ring, for example.

Preferably, the laser diode holder 260 is arranged at least in sections in the carrier tube 211. The laser diode holder 260 has, by way of example, a tubular base body 261 with the interior receptacle 263, in which the laser diode 135 is illustratively arranged. Preferably, the tubular base body 261 of the laser diode holder 260 has a circumferential collar 264. The circumferential collar 264 extends radially 202 away from the tubular base body in the shape of a plate, as illustrated.

Preferably, the carrier tube 211 has a first abutment surface 243 on its outer circumference 218 and a second abutment surface 244 on the top side 249 of a circumferential collar 213.

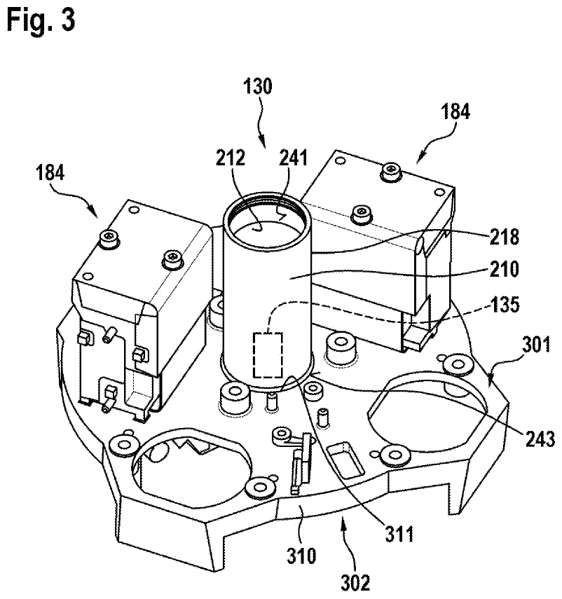

FIG. 3 shows a base plate 310 associated with the rotary laser 100 of FIG. 1. The base plate 310 is preferably movably mounted in the housing 110 of the rotary laser 100. The base plate 310 has a top side 301 and a bottom side 302. By way of example, at least one, illustratively two, inclination sensors 184 of the leveling unit 180 of FIG. 1 are arranged on the top side 301.

Furthermore, the base plate 310 illustratively has a central recess 311. The base plate 310 is preferably provided for the arrangement of the carrier tube 211 of FIG. 2. Here, the carrier tube 211 is preferably designed to engage at least in sections in the central recess 311 of the base plate 310.

Preferably, the first abutment surface 243 of the carrier tube 211 is located in the central recess 311. Furthermore, the second abutment surface 244 is preferably located on the bottom side 302 of the base plate 310. The carrier tube 211 is preferably machined at at least one of the first and second abutment surfaces 243, 244 to orthogonally align the spindle 125 with a laser beam (911 in FIG. 9) by way of adjustment turning. Such machining of the first abutment surface 243 makes it possible to align the laser beam (911 in FIG. 9) centrally and orthogonally to the base plate 310. Furthermore, the bearing surfaces 241, 242, which may also be referred to as bearing seats, are aligned centrally with respect to the base plate 310.

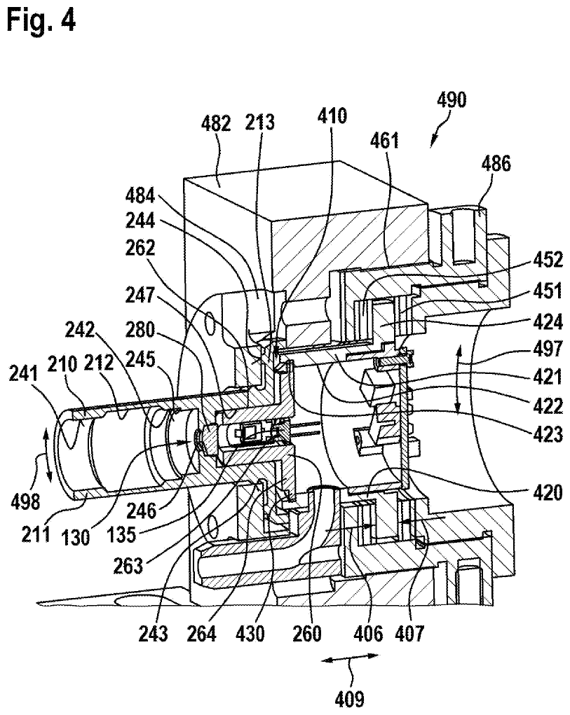

FIG. 4 shows an example press-fitting device 490 for press-fitting the laser diode holder 260 of FIG. 2 into the carrier tube 211 of FIG. 2 during a press-fitting process. The stator 210 of FIG. 2, or the carrier tube 211, is preferably secured to a holding device 482 of the press-fitting device 490 by way of a first holding part 484.

The tubular base body 261 of the laser diode holder 260 has, as described above in FIG. 2, the circumferential collar 264, which preferably has at least two radial extensions 430 in the circumferential direction 498 of the laser diode holder 260 for detachable connection to the press-fitting device 490 for press-fitting the laser diode holder 260 into the carrier tube 211. Preferably, the detachable connection is designed to transmit compressive and/or tensile forces. This is illustrated, for example, by arrows 406, 407. In particular, the detachable connection is preferably designed as a detachable bayonet connection 410. Preferably, the at least two radial extensions 430 are formed to form the detachable bayonet connection 410 with the press-fitting device 490.

Furthermore, the press-fitting device 490 illustratively has the first holding part 484 for holding the carrier tube 211 and a second holding part 420 for holding the laser diode holder 260. The second holding part 420 preferably has, in the circumferential direction 497, at least one undercut 423 in sections to form a detachable connection with the laser unit 130. To form the bayonet connection 410, the at least two radial extensions 430 are preferably arranged in the at least one undercut 423. The at least one undercut 423 of the second holding part 420 is preferably formed in sections in the circumferential direction 497 of the second holding part 420.

The second holding part 420 illustratively has a cylindrical base body 421 with an interior receptacle 422. At its illustratively left end, the interior receptacle 422 has an undercut 423. At its illustratively right end, the second holding part 420 illustratively has a circumferential collar 424. Preferably, the second holding part 420 is mounted via the circumferential collar 424 by way of bearing elements 451, 452 in the press-fitting device 490, in particular a bracket 486. The bracket 486 is, for example, arranged in the holding device 482 via a threaded connection 461. Preferably, the threaded connection 461 has a fine thread.

The laser diode holder 260 is preferably pressed into the interior receptacle 212 of the stator 210 along a longitudinal extension 409 of the stator 210 by applying force to the first holding part 420 relative to the second holding part 484.

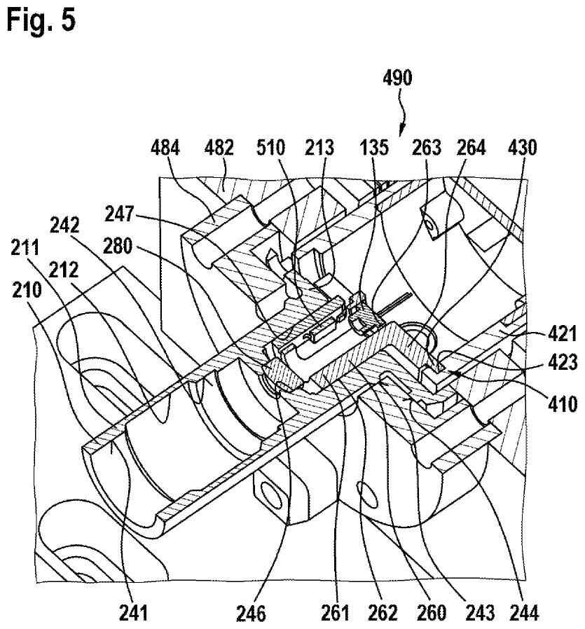

FIG. 5 shows the press-fitting device 490 and the laser diode holder 260 as well as the carrier tube 211 of FIG. 4. The laser diode 135 is preferably associated with a monitor diode. The monitor diode is preferably configured to measure a laser output assigned to the laser diode 135. Here, the monitor diode may be a monitor diode integrated into the laser diode 135. Preferably, the laser unit 130 has a photodiode 510, which is provided for measuring the laser output independently of the monitor diode. Illustratively, the photodiode 510 is arranged perpendicular to the laser diode 135.

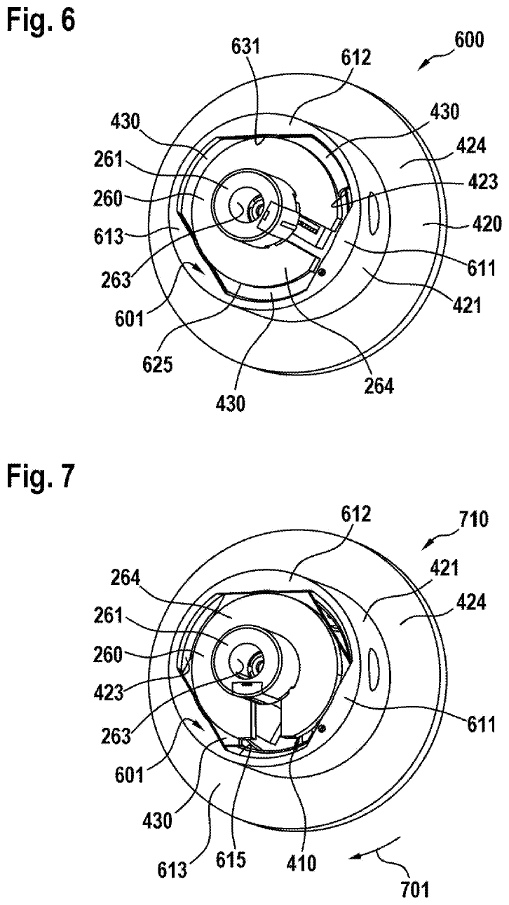

FIG. 6 shows the second holding part 420 of the press-fitting device 490 of FIG. 4 and FIG. 5 with the laser diode holder 260 of FIG. 2 to FIG. 5 in a joining position 600. Preferably, the laser diode holder 260 has at least two, illustratively three radial extensions 430. Similarly, the second holding part 420 preferably has a recess 615 associated with the laser diode holder 260 or the illustrative three radial extensions 430 on its end face 601. Preferably, the second holding part 420 has three cover webs 611, 612, 613 on its end face 601, which cover the undercut 423 in sections. Furthermore, recess 615 has, for illustrative purposes, a bulge 631 located in the center of a cover web 611, 612, 613, which corresponds to an outer circumference 625 of the circumferential collar 264 of the laser diode holder 260.

FIG. 7 shows the second holding part 420 of the press-fitting device 490 with the laser diode holder 260 of FIG. 6 in a locked position 700. In FIG. 7, the second holding part 420 and the laser diode holder 260 are illustratively arranged rotated relative to each other in the circumferential direction 701 with respect to the joining position 600 in FIG. 6. Preferably, the second holding part 420 and the laser diode holder 260 are rotated by 60° relative to each other in the circumferential direction 701.

In the locked position 700, the three radial extensions 430 of the laser diode holder 260 are shown, by way of example, arranged in the undercut 423, wherein the cover webs 611, 612, 613 engage the radial extensions 430 in the undercut 423. Here, the laser diode holder 260 and the second holding part 420 illustratively form the bayonet connection 410.

In an exemplary method for mounting the laser diode holder 260 of the laser unit 130 of the rotary laser 100 in the carrier tube 211 of the stator 210, the laser diode holder 260 is preferably first arranged in the joining position 600 of FIG. 6 on the second holding part 420 of the press-fitting device 490 of FIG. 4 and FIG. 5. Subsequently, the laser diode holder 260 is rotated by a predetermined angle of rotation along the circumferential direction 701 to the arrangement in the locked position 700, in which the laser diode holder 260 and the second holding part 420 form the bayonet connection 410. fixing the stator (210) to a first holding part (484) of the press-fitting device (490), The laser diode holder 260 is then pressed into the interior receptacle 212 of the stator 210 along the longitudinal extension 409 of the stator 210 by applying force to the second holding part 420 relative to the first holding part 484. The laser diode holder 260 is then rotated relative to the press-fitting device 490 against the circumferential direction 701 to rotate the laser diode holder 260 from the locked position 700 to the joining position 600. Finally, the first and second holding parts 484, 420 are removed from the laser diode holder 260 and the carrier tube 211 of the stator 210.

As described above, the at least two radial extensions 430 of the laser diode holder 260 are preferably arranged in the at least one undercut 423 of the second holding part 420 to form the bayonet connection 410.

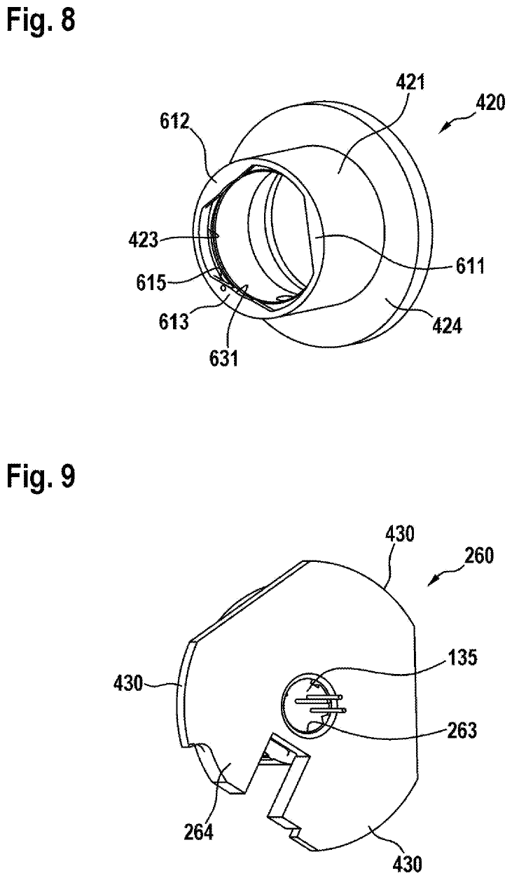

FIG. 8 shows the second holding part 420 of FIG. 4 to FIG. 7 with the cylindrical base body 421, the undercut 423 and the circumferential collar 424. FIG. 8 illustrates the recess 615 with the cover webs 611, 612, 613 and the bulge 631.

FIG. 9 shows the laser diode holder 260 of FIG. 2 to FIG. 7. FIG. 9 illustrates the circumferential collar 264 of the laser diode holder 260 with the three exemplary radial extensions 430.

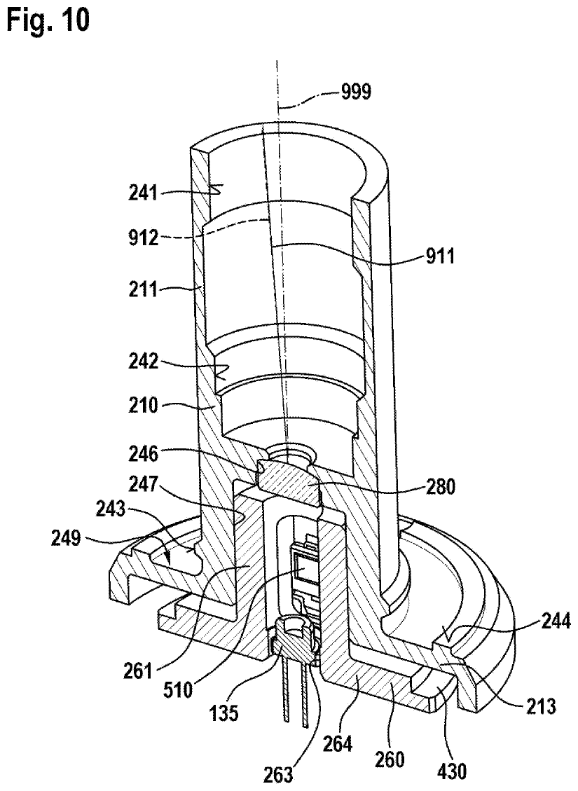

FIG. 10 shows the stator 210 with the carrier tube 211 and the laser diode holder 260 arranged in sections in the carrier tube 211 with the laser diode 135, the photodiode 510 and the collimating lens 280 of FIG. 2, FIG. 4 and FIG. 5. A laser beam 911 generated by the laser diode 135 and collimated by the collimating lens 280, as well as a laser axis 912 associated with the laser beam 911, are not shown as congruent with an axis of rotation 999 of the spindle or the carrier tube 211, but are instead shown as being angled relative to it. Such a tilt and/or lateral offset can occur during the installation of laser diode 135 in laser diode holder 260, the installation of laser diode holder 260 in carrier tube 211, and/or the installation of collimating lens 280 in carrier tube 211.

To compensate for the tilt and/or lateral offset of the laser beam 911 relative to the axis of rotation 999 within specified tolerances, or to achieve a congruent alignment of the rotational axis 999 of the spindle 125 with the laser beam 911 of the laser diode 135, the carrier tube 211 is preferably machined by way of adjustment turning.

In a conventional turning process, a workpiece is clamped onto a spindle that is stationary and can only rotate. Therefore, only rotationally symmetrical geometries can be produced or spiral-shaped geometries such as threads. During adjustment turning, the spindle can also perform a sideways movement. The various movements, e.g. rotation, sideways movement of the spindle, feed of the tool, can be precisely controlled via a computer. In this way, “non-round” contours can be created. This capability enables the correction of an oblique laser axis, such as laser axis 912.

As described above, the interior receptacle 212 of the carrier tube 211 includes at least two bearing surfaces 241, 242 for mounting the bearing elements 231, 232, which support the spindle 125 of FIGS. 1 and 2 in rotary movement. Preferably, the carrier tube 211 is machined on at least one of the at least two bearing surfaces 241, 242 for concentric alignment of the spindle 125 to the laser beam 911 by way of adjustment turning.

Furthermore, as described above, the carrier tube 211 preferably has the first abutment surface 243 on its outer circumference 218 and/or the second abutment surface 244 on the top side 249 of the circumferential collar 213, wherein the first abutment surface 243 is exemplary arranged in the central recess 311 of FIG. 3 and the second abutment surface 244 is arranged on the bottom side 302 of the base plate 310. Alternatively, or optionally, the carrier tube 211 is machined at the first abutment surface 243 to allow for the centric alignment of the spindle 125 or the laser beam 911 relative to the base plate 310 in FIG. 3 by way of adjustment turning. Alternatively, or optionally, the carrier tube 211 is machined at the second abutment surface 244 by way of adjustment turning to ensure orthogonal alignment of the spindle 125 or the laser beam 911 relative to the base plate 310 in FIG. 3.

Preferably, during the adjustment turning of the stator 210 or the carrier tube 211, at least one of the surfaces 241, 242, 243, 244 associated with the carrier tube 211 is machined—in particular, by cutting—based on a virtual axis of rotation defined by the laser axis 912. In this context, preferably at least one of the bearing surfaces 241, 242 forms such an associated surface. Alternatively, or optionally, the first and/or second abutment surface 243, 244 forms such an associated surface. By machining the carrier tube 210 along the virtual axis of rotation, preferably at least one of the associated surfaces 241, 242, 243, 244 is machined such that the axis of rotation 999 of the spindle 125 is congruent with the laser beam 911.

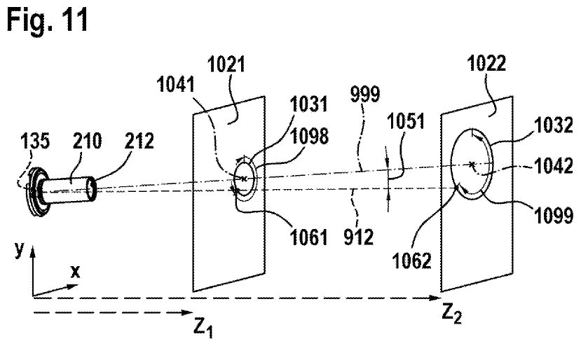

FIG. 11 shows the stator 210 from FIG. 10 during a process for congruently aligning the axis of rotation 999 of the spindle 125 of the rotary laser 100 with the laser axis 912 of the laser beam 911 generated by the laser diode 135 of the laser unit 130 of the rotary laser 100.

The installation-induced tilt of the laser diode holder 260 in the carrier tube 211 causes a tilt and/or lateral offset of the laser axis 912 of the laser beam 911 relative to the axis of rotation 999 of the spindle 125, wherein the tilt and/or lateral offset are compensated for by way of adjustment turning. For this purpose, the laser axis 912 is first measured to determine the existing tilt and/or the lateral offset of the laser axis 912 relative to the axis of rotation 999.

When measuring the laser axis 912, a rotating laser beam 1031, 1032 is first detected in a first plane 1021 perpendicular to the axis of rotation 999 of the spindle 125 and in a second plane 1022 perpendicular to the axis of rotation 999 of the spindle 125. Here, the perpendicular planes 1021, 1022 are arranged at different distances z1, z2 from the laser diode 135. Subsequently, a center point 1041, 1042 of the rotating laser beam 1031, 1032 in the first and second plane 1021, 1022 is preferably determined to define an associated axis of rotation of the laser beam 1031, 1032. This is followed by the detection of a first laser spot 1061 associated with the first rotating laser beam 1031 at a first rotation angle 1098 of the first rotating laser beam 1031, and a second laser point 1062 associated with the second rotating laser beam 1032 may be captured at a second rotation angle 1099 of the second rotating laser beam 1032. The first and second rotation angles 1098, 1099 are preferably identical. Finally, the present tilt 1051 and/or the lateral offset of the laser axis 912 relative to the axis of rotation 999 is determined by way of the recorded first and second laser points 1061, 1062.

If there is a tilt and/or lateral offset of the laser axis 912 relative to the axis of rotation 999, the adjustment turning described above is performed on at least one of the surfaces 241, 242, 243, 244 associated with the carrier tube 211, to compensate for the existing tilt and/or lateral offset, thereby achieving a congruent alignment of the laser axis 912 with the axis of rotation 999.

What is claimed is:

1. A laser unit for a rotary laser, wherein the rotary laser has a drive unit for rotating a spindle for rotary drive of a laser beam, and wherein the drive unit has a stator with a carrier tube and a rotor configured for rotary drive of the spindle, the laser unit comprising:
a beam deflector arranged on the spindle and configured to deflect the laser beam; and
a laser diode holder arranged at least in sections within the carrier tube,
wherein the laser diode holder has a tubular base body with an interior receptacle in which a laser diode is arranged, and
wherein the tubular base body of the laser diode holder has a circumferential collar which, in a circumferential direction of the laser diode holder, has at least two radial extensions configured for a detachable connection to a press-fitting device for press-fitting the laser diode holder into the carrier tube.

2. The laser unit according to claim 1, wherein the detachable connection is designed to transmit compressive and/or tensile forces.

3. The laser unit according to claim 1, wherein the circumferential collar extends away from the tubular base body in the shape of a plate.

4. The laser unit according to claim 1, wherein at least two radial extensions are configured to form a detachable bayonet connection with the press-fitting device.

5. A press-fitting device for press-fitting a laser diode holder of a laser unit into a carrier tube of a stator of a drive unit of a rotary laser, the press-fitting device comprising:
a first holding part configured to hold the carrier tube; and
a second holding part configured to hold the laser diode holder,
wherein the second holding part has, in a circumferential direction, at least one undercut in sections to form a detachable connection with the laser unit.

6. The press-fitting device according to claim 5, wherein:
in a locked position, the laser diode holder and the second holding part form a bayonet connection for pressing-fitting the laser diode holder into the carrier tube.

7. The press-fitting device according to claim 6, wherein the bayonet connection is designed to transmit compressive and/or tensile forces.

8. A rotary laser comprising a laser unit according to claim 1.

9. A method for mounting a laser diode holder of a laser unit of a rotary laser in a carrier tube of a stator, the method comprising:
positioning the laser diode holder in a joining position on a second holding part of a press-fitting device;
rotating the laser diode holder by a predetermined angle of rotation along a circumferential direction to position it in a locked position in which the laser diode holder and the second holding part form a bayonet connection;
fixing the stator to a first holding part of the press-fitting device;
pressing the laser diode holder into an interior receptacle of the stator along its longitudinal extension by applying force to the second holding part relative to the first holding part;
rotating the laser diode holder relative to the press-fitting device counter to the circumferential direction to rotate the laser diode holder from the locked position to the joining position; and
removing the first and second holding parts from the laser diode holder and the carrier tube of the stator.

10. The method according to claim 9, wherein:
the laser diode holder has at least two radial extensions and the second holding part has at least one undercut, and
to form the bayonet connection, the at least two radial extensions are arranged in the at least one undercut.
